(19) United States
(12) Patent Application Publication
(10) Pub. No.: US 2026/0212286 A1
(43) Pub. Date: Jul. 23, 2026

(54) SYSTEMS AND METHODS FOR WATER MANAGEMENT OF OIL AND GAS PRODUCTION SYSTEMS

(71) Applicant: ConocoPhillips Company, Houston, TX (US)

(72) Inventors: Michael M. McGARVEY, Houston, TX (US); Mazaruny RINCONES, Houston, TX (US); Chung-Kan HUANG, Houston, TX (US); Dylan VENNES, Houston, TX (US); Hui ZHOU, Houston, TX (US); Qin LU, Houston, TX (US); Izuchukwu Samuel ILONZE, Houston, TX (US); Michael BURKARD, Houston, TX (US); Rafael E. PAZ LOPEZ, Houston, TX (US)

(21) Appl. No.: 19/456,380

(22) Filed: Jan. 22, 2026

Related U.S. Application Data
(60) Provisional application No. 63/820,168, filed on Jun. 9, 2025.
(60) Provisional application No. 63/748,558, filed on Jan. 23, 2025.

(51) Int. Cl. G06Q 10/04; G06F 30/20; G06Q 10/0631

(52) U.S. Cl. CPC G06Q 10/04; G06F 30/20; G06Q 10/06312

(57) ABSTRACT

Implementations claimed and described herein provide systems and methods for optimizing a development plan for natural resource production. The systems and methods use a water production forecast and a pressure simulation to generate an optimized development plan.

### CROSS-REFERENCE TO RELATED APPLICATIONS

The present application claims priority to U.S. Provisional Patent Application No. 63/748,558 filed on January 23, 2025, and U.S. Provisional Patent Application No. 63/820,168 filed on June 9, 2025. Each of these applications is incorporated by reference in its entirety herein.

### FIELD

Aspects of the presently disclosed technology relate generally to optimization of a development plan for natural resource production and more specifically to optimization of water management development plans for oil and gas production systems.

### BACKGROUND

Oil and gas production systems output water as a product of the production process. This water is also known as produced water or saltwater and is a hazardous byproduct of oil and gas production because it contains high levels of salt, hydrocarbons, and other compounds. This water must be disposed of in a process known as saltwater disposal (SWD). SWD uses a number of disposal wells to pump the saltwater into the ground. A large number of complex factors can cause more produced water and/or formation pressure than expected, such as, unexpectedly high production, geology, number of disposal wells, adjacent wells, well spacing, etc. that can damage well economics by subsurface contamination and creating future drilling complications. It is with these observations in mind, among others, that various aspects of the present disclosure were conceived and developed.

### SUMMARY

Implementations described and claimed herein address the foregoing problems by providing systems and methods for optimizing oil and gas production systems for water disposal management. The implementations described and claimed herein utilize probabilistic water forecasting with pressure prediction simulations to create a feedback loop that continuously redefines development plans of disposal wells for oil and gas systems. Thus, the implementations described and claimed herein allow for using the complex interaction of well completions, geology, and well spacing to optimize a development plan of oil and gas systems, thereby minimizing planning costs and subsurface containment risks.

In some implementations, a system for optimizing a natural resource production system, the system comprises: a processing system in communication with a computing device, one or more sensors and one or more databases over a network, the processing system obtaining data associated with the natural resource production system from at least one of the computing device, the one or more sensors or the one or more databases; a water production estimation system generating water production forecast data using the data, the water production forecast data used by a pressure estimation system to generate pressure simulation data; and a well plan optimization system using the pressure simulation data and the water production forecast data to generate an optimized development plan.

In some implementations, a method for optimizing a natural resource production system, the method comprising: receiving data associated with the natural resource production system from at least one of a computing device, one or more sensors or one or more databases; generating water production forecast data using the data; generating pressure simulation data using the water production forecast data; and generating an optimized development plan using the pressure simulation data and the water production forecast data.

In some implementations, one or more tangible non-transitory computer-readable storage media storing computer-executable instructions for performing a computer process on a computing system, the computer process comprising: receive data associated with a natural resource production system; generate water production forecast data using the data; generate pressure simulation data using the water production forecast data; and generate an optimized development plan using the pressure simulation data and the water production forecast data.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

FIG. 1 illustrates an example water management optimization system.

FIG. 2 illustrates an example processing system.

FIG. 3 illustrates an example computing system that may implement various aspects of the communication system.

FIG. 4 illustrates example operations for optimizing a development plan for a natural resource production system.

FIG. 5 illustrates an example graphical representation of a water forecast that can be used and/or generated using the various systems and methods discussed herein.

FIG. 6 illustrates an example graphical representation of a pressure prediction that can be used and/or generated using the various systems and methods discussed herein.

FIG. 7 illustrates an example graphical representation of a base well allocation that can be used and/or generated using the various systems and methods discussed herein.

FIG. 8 illustrates an example graphical representation of a new well allocation that can be used and/or generated using the various systems and methods discussed herein.

FIG. 9 illustrates an example graphical representation of a water production forecast that can be used and/or generated using the various systems and methods discussed herein.

FIG. 10 illustrates an example graphical representation of a pressure prediction for a reservoir that can be used and/or generated using the various systems and methods discussed herein.

FIG. 11 illustrates an example graphical representation of a pressure prediction for a reservoir that can be used and/or generated using the various systems and methods discussed herein.

FIG. 12 illustrates an example graphical representation of training data that can be used and/or generated using the various systems and methods discussed herein.

FIG. 13 illustrates an example graphical representation of a capacity prediction for a disposal that can be used and/or generated using the various systems and methods discussed herein.

FIG. 14 illustrates an example graphical representation of a pressure prediction for a reservoir that can be used and/or generated using the various systems and methods discussed herein.

### DETAILED DESCRIPTION

Aspects of the present disclosure involve systems and methods to process a large amount of data associated with the complex interaction of well completions, geology, and well spacing. The systems and methods described herein generate probabilistic water forecasting and pressure prediction simulations to create a feedback loop that continuously redefines development plans of disposal wells for oil and gas systems, for real time analysis and optimization. This results in a more efficient platform that provides effective water management for water produced by production systems in the oil and gas industry. Additional advantages of the presently disclosed technology will become apparent from the detailed description below.

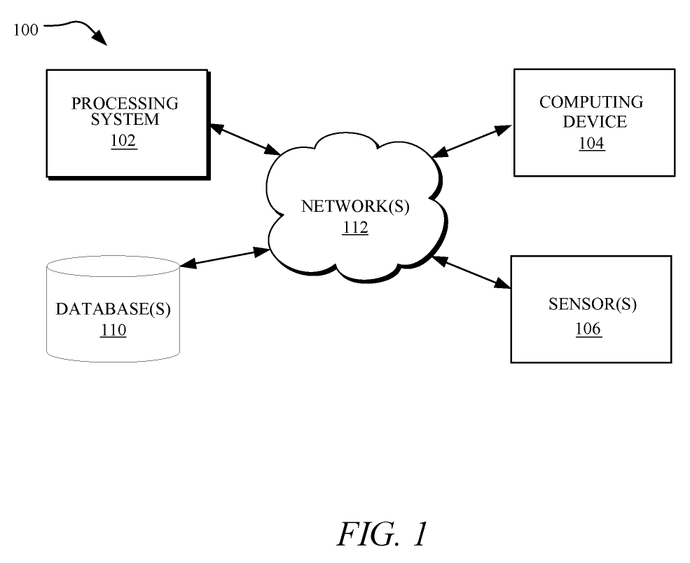

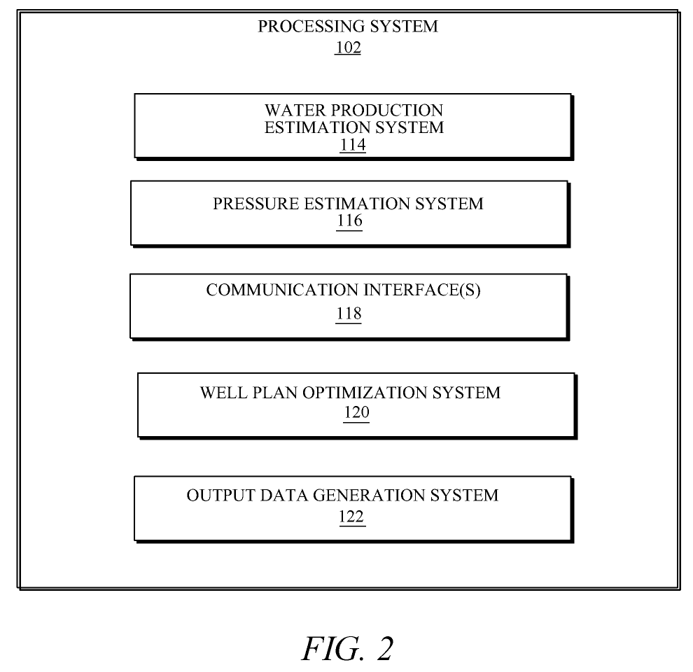

To begin a detailed description of an example system 100 for optimization of development plans for water management of natural resource production systems. In an implementation, the natural resource production systems include one or more wells used to extract oil or gas and/or dispose produced water. In an implementation, the system 100 processes data and generates a water prediction forecast and a pressure simulation for use in analyzing and optimizing development plans for water management of oil and gas production systems, reference is made to FIGS. 1-14. In an implementation, the data includes at least one of disposal well injection rates and pressure data, disposal zone pressure data derived from injection surface pressure data and mud weight data from well kick events, probabilistic base water forecasts for one or more wells (for example, operated wells, operated by others wells, and non-working interest wells), development water forecasts for the one or more wells (e.g., operated wells and operated by others wells, where it is assumed that non-working interest wells development water forecast is extrapolated from current activity rates), location data, or disposal well permit data. The system 100 can include a processing system 102 configured to obtain data from at least one of one or more sensors 106 or one or more databases 110. In an implementation, at least a portion of the data is obtained by one or more sensors 106 disposed in a well or at a surface during well tests or reservoir tests and/or well operation. For instance, the pressure and flow rate are continuously monitored throughout operation of the well using one or more pressure sensors and one or more flow rate sensors. The system 100 is configured to receive user inputs via one or more input systems using, for example, the computing device 104 to input text, audio, and/or interact with an interactive user interface displayed on one or more output systems of, for example, the computing device 104. The processing system 102, the computing device 104, the one or more sensors 106, and the one or more databases 110 are configured to interact with one another via a network(s) 112. In an implementation, the data is received directly from the one or more sensors 106 via a wired or wireless connection. As illustrated in greater detail below, any and/or all of the processing system 102, the computing device 104, and the one or more databases 110 may, in some instances, be special-purpose computing devices configured to perform specific functions.

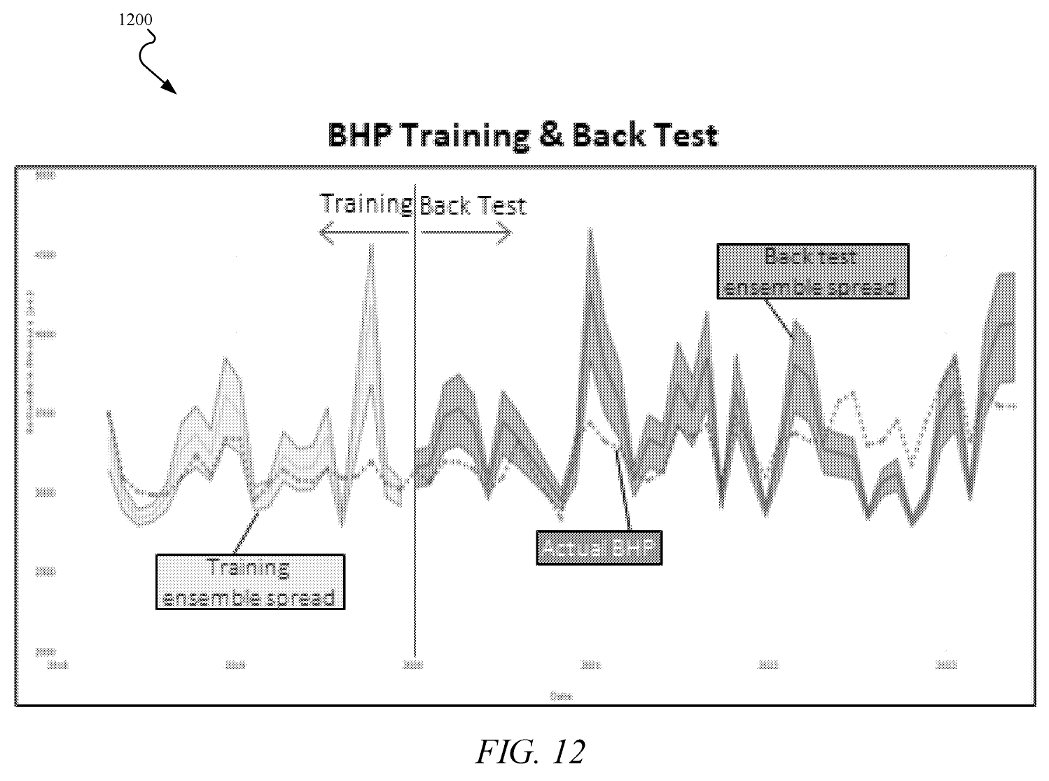

The processing system 102 includes one or more computing devices (e.g., servers, routers, user interface devices, internet telephony computing device, and the like) that store and/or retrieve data in the one or more databases 110, generate user interfaces, execute a water production estimation system 114, a pressure estimation system 116, a well plan optimization system 120, an output data generation system 122 , etc. by processing instructions. The processing system 102 may include a communication interface(s) 118 that is able to communicate with the one or more input systems and one or more output systems via the network(s) 112 . For instance, the communication interface(s) 118 may be a network interface configured to support communication between the processing system 102 and the network(s) 112 . The one or more input systems and one or more output systems may be part of the computing device 104 or separate from the computing device 104. The processing system 102 can be configured to execute one or more algorithms to perform the techniques, as discussed in greater detail below. For instance, the one or more algorithms can include one or more machine learning algorithms. The one or more machine learning algorithms can be one or more models, such as, for example, a linear regression model, an unsupervised neural network model, gradient boosted trees, random decision forest, etc. The one or more machine learning models may be built from historical data associated with natural resource production systems that is stored, for example, at one or more databases. In an implementation, the one or more machine learning models are trained using historical disposal zone pressure data, such as, for example, well kick events, mud weights, and bottom hole pressure of one or more disposal wells. In an implementation, the one or more machine learning models are validated using QAQC model history match and/or back testing, such as the graphical representation 1200 in FIG. 12. Thus, the one or more machine learning models leverages historical data to generate optimized water management development plans. The processing system 102 can be configured to monitor and store (e.g., with appropriate permissions) data for further analysis and/or training of the machine learning model. In an implementation, the processing system 102 is configured to transmit the communication to another computing device or database, such as the one or more databases 110. In an implementation, the processing system 102 is associated with an organization or entity.

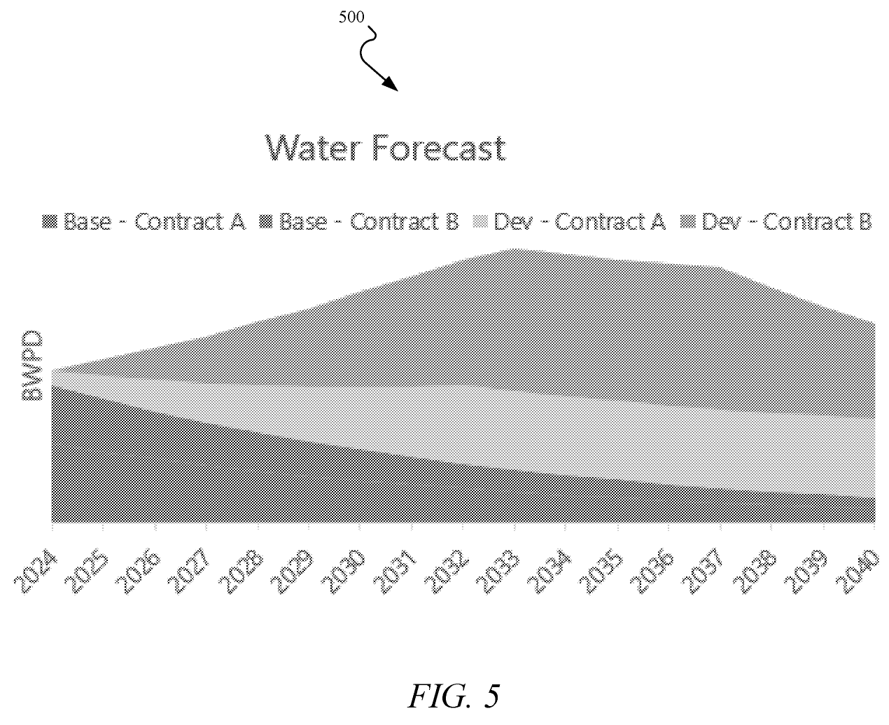

In an implementation, the computing device 104 includes one or more input systems and one or more output systems. For instance, t he operator is able to input data associated with one or more wells to the processing system 102 via one or more interactive user interfaces using the computing device 104. The computing device 104 can be a smartphone, a tablet, a desktop computer, a laptop computer, or other personal computing device that may be used by an individual (e.g., the operator) to receive notification(s) and enter data. In some instances, the computing device 104 may be used to display plots, analytical information, notifications and/or other alerts using graphical user interfaces, such as, for example, the graphical representations illustrated in FIGS. 5-14.

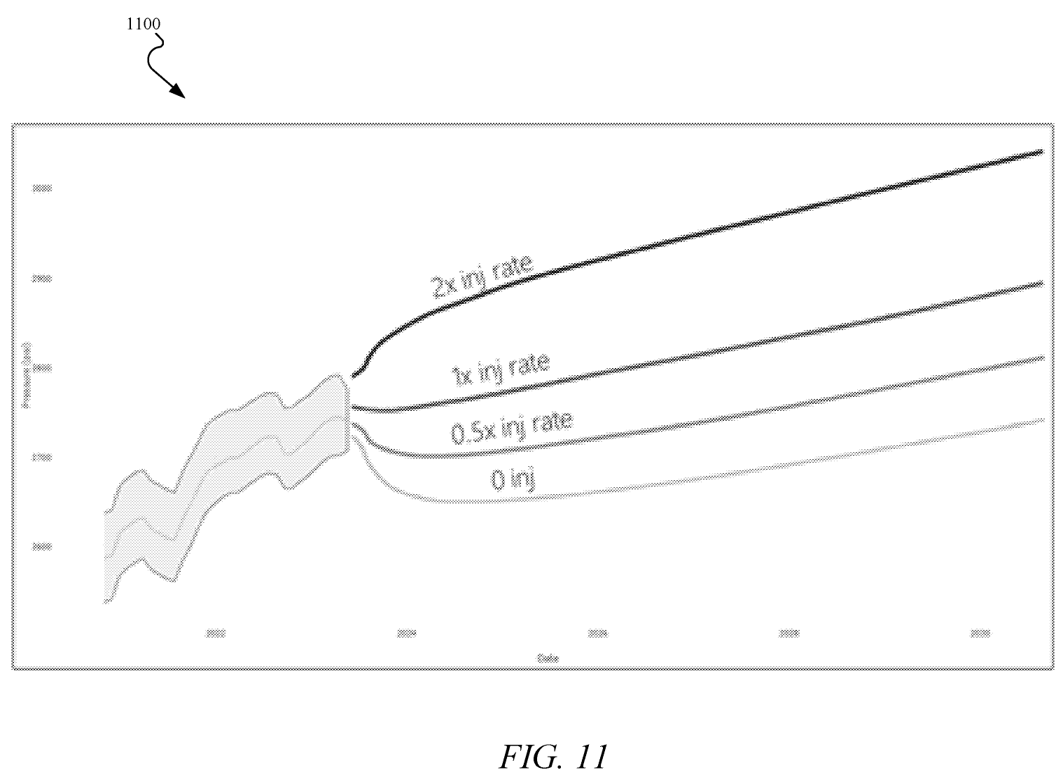

In an implementation, the processing system 102 includes instructions that direct and/or cause the water production estimation system 114 to execute processing techniques on the data to generate water forecast data for one or more wells. The water forecast data is input into the pressure estimation system 116 to generate pressure prediction data. In an implementation, the pressure prediction data can be generated for numerous injection scenarios, such as the graphical representation 1100 in FIG. 11. The water production estimation system 114 and/or the pressure estimation system 116 can be configured to execute one or more algorithms to perform the techniques. For instance, the one or more algorithms can include one or more machine learning algorithms. The one or more machine learning algorithms can be one or more models, such as, for example, a linear regression model, an unsupervised neural network model, gradient boosted trees, random decision forest, etc. The one or more machine learning models may be built from historical data associated with oil and gas production systems that is stored, for example, at one or more databases 110. In an implementation, the water forecast data and/or the pressure prediction data is generated by processing large amounts of data associated with a large number of oil and gas production systems (e.g., well completions, geology, and well spacing, etc.), in real-time or near real-time, to allow for analysis of an oil or gas production system to assist in optimization decisions, such as, for example, development plans involving well spacing, well completions, well designs (e.g., needing additional casing strings), protests of well permits, well operations (e.g., drilling schedules), and/or legal agreements (e.g., water offtake contracts).

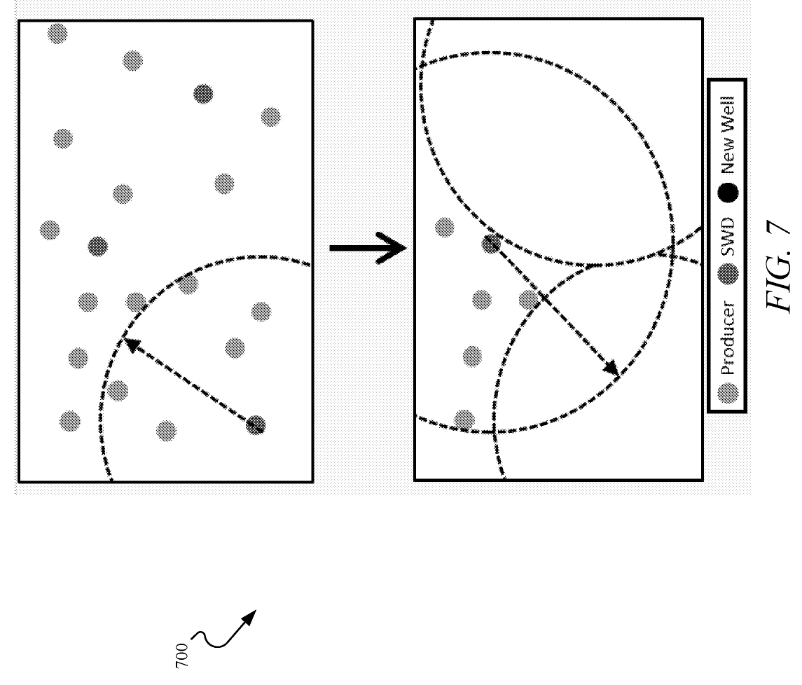

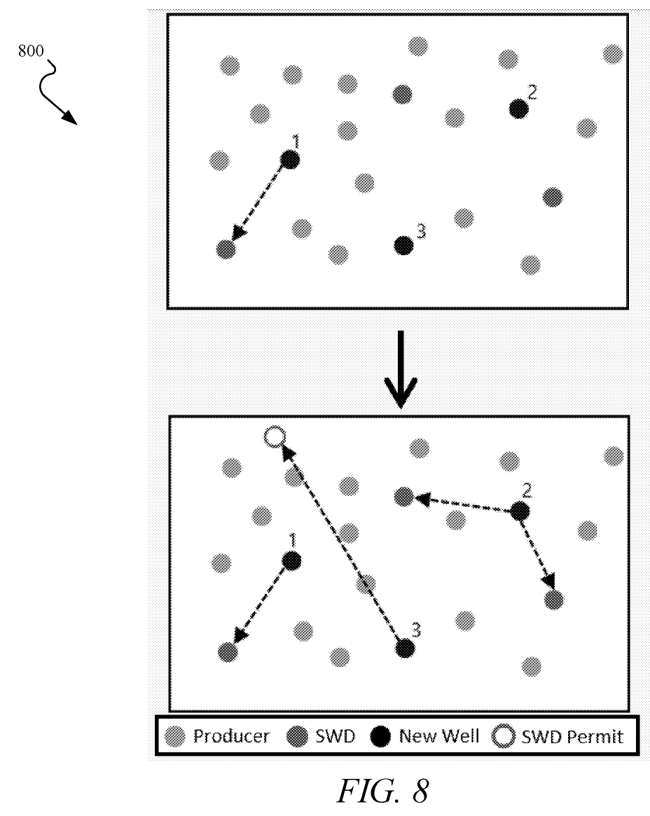

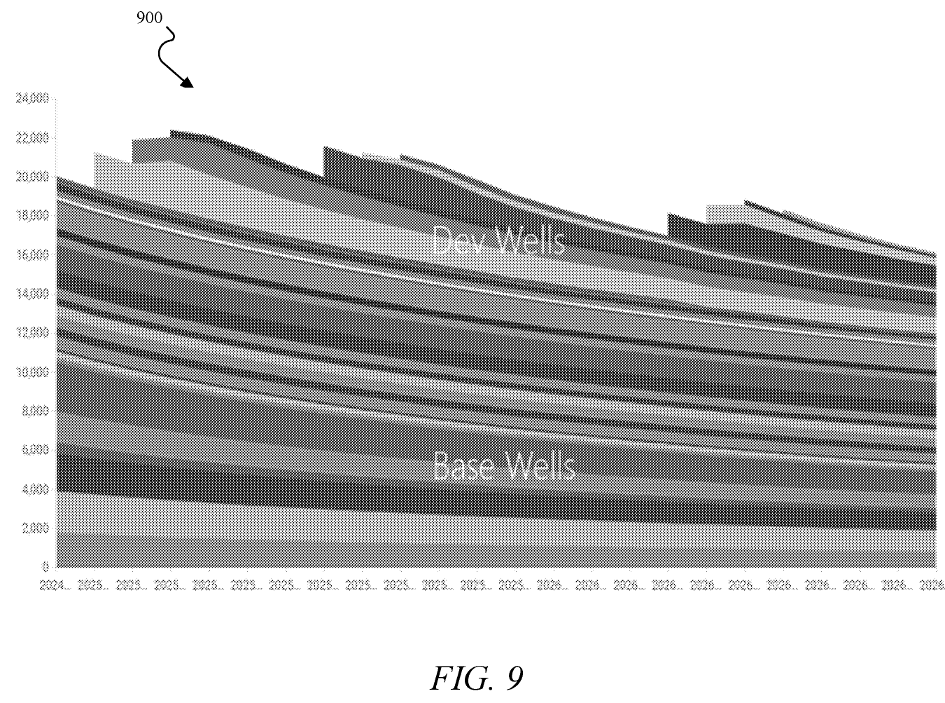

In an implementation, the water production estimation system 114 uses a statistical algorithm, such as, for example, Markov chain Monte Carlo (MCMC), to generate water forecast data for current wells. In an implementation, new wells are estimated from well permits and/or development plans. In an implementation, the current wells are allocated to nearby disposal wells by, for example, matching production of the current wells to capacity of the disposal wells within a radius, such as the graphical representation 700 in FIG. 7. In an implementation, the new wells are allocated to nearby disposal wells with sufficient capacity, such as the graphical representation 800 in FIG. 8. In an implementation, new disposal wells are added using permit data and/or development plans. As illustrated by the graphical representation 900 in FIG. 9, the disposal well forecast is the sum of the production forecast of the allocated wells.

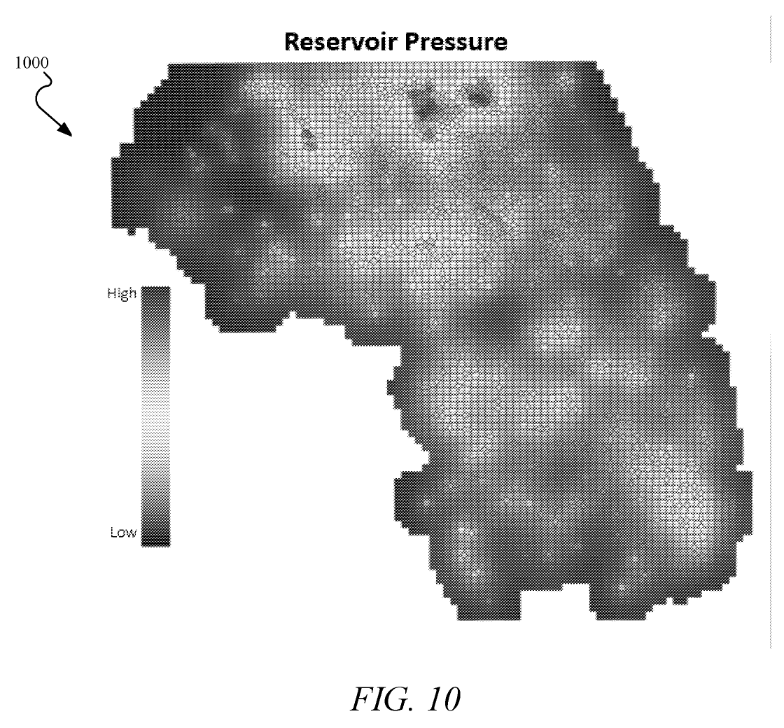

In an implementation, the processing system 102 includes instructions that direct and/or cause the well plan optimization system 120 to perform one or more of the functions described herein using the water forecast data and/or the pressure prediction data. For example, the well plan optimization system 120 is configured to optimize a development plan for an oil and gas system using the water forecast data and/or the pressure prediction data. In an implementation, the well plan optimization system 120 is configured to generate one or more pressure maps and/or water forecasts by area, such as, for example, a model of regional pressure of a disposal zone, as illustrated in the graphical representation 1000 in FIG. 10. In this implementation, the one or more pressure maps can indicate which future planned wells need additional structure (e.g., casing strings). In an implementation, the one or more pressure maps morphs geology to fit training data. In an implementation, the pressure prediction data is determined in real-time to allow for live data integration. In an implementation, the well plan optimization system 120 is configured to link the one or more pressure maps to associated well permits. In an implementation, the well plan optimization system 120 is configured to adjust drilling and/or well operations. For instance, the well plan optimization system 120 is configured to optimize the development plan by adjusting drilling schedules to avoid high-pressure areas and/or accelerate development in active areas, adjust well spacing, adjust well completion, well design, etc. The optimized development plan is then used by the water production estimation system 114 and/or the pressure estimation system 116 to update the water forecast data and/or the pressure prediction data.

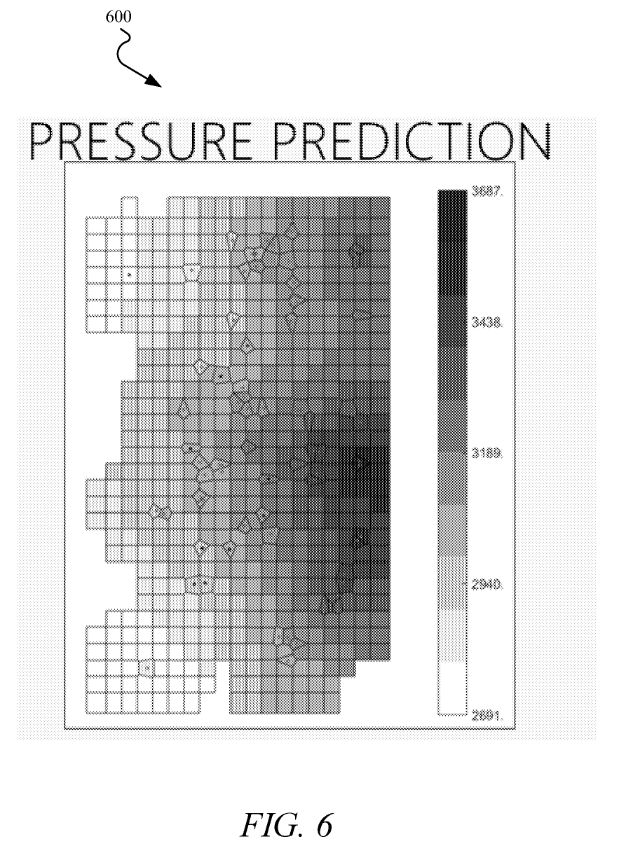

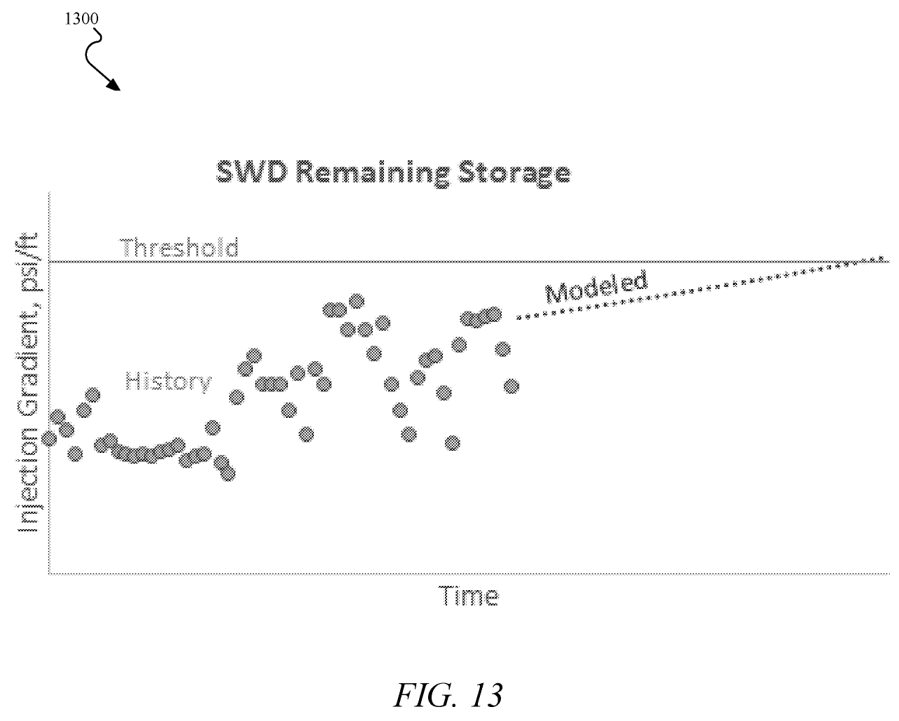

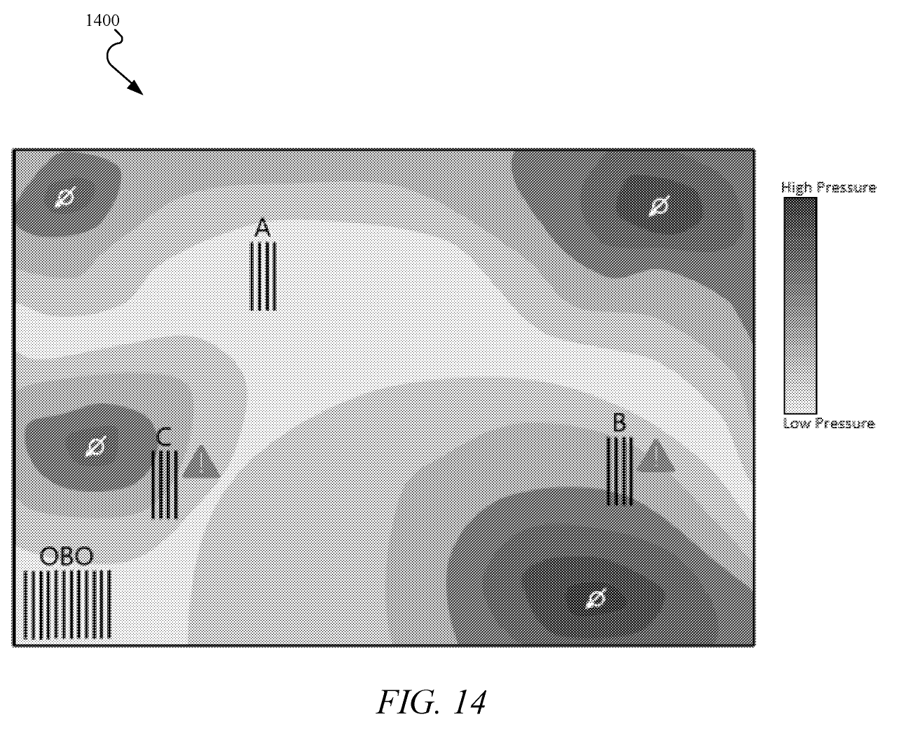

In an implementation, the processing system 102 includes instructions that direct and/or cause the output data generation system 122to perform one or more of the functions described herein. In an implementation, the output data generation system 122 is configured to generate a notification regarding the optimized development plan, the one or more pressure maps, and/or water forecasts. In an implementation, the output data generation system 122 is configured to output a notification to protest one or more well permits. For instance, the notification is audio, visual, and/or textual notification. In an implementation, the notification indicates a plot of analyzed data using the pressure maps and/or water forecasts, such as the graphical representations 500 and 600 in FIGS. 5 and 6. In an implementation, the notification indicates a plot of remaining disposal capacity relative to a threshold using the pressure maps and/or water forecasts, such as the graphical representation 1300 in FIG. 13. In another implementation, the notification indicates that one or more planned production systems require optimization (e.g., changing of drilling schedule) and/or have been optimized by the well plan optimization system 120, such as the graphical representation 1400 in FIG. 14. In an implementation, the notification is presented via one or more interactive user interfaces generated by the output data generation system 122 and transmitted, via the communication interface(s) 118, to the computing device 104 for display by the output system of the computing device 104. In an implementation, the notification may be sent upon request and/or periodically to the computing device 104, such as, for example, a report in an e-mail. For instance, the notification may be sent, hourly, daily, weekly, monthly, etc. In an implementation, the output data generation system 122 outputs instructions to control the resource production system in accordance with the optimized development plan.

The network(s) 112 can be any combination of one or more of a cellular network such as a 3rd Generation Partnership Project (3GPP) network, a third generation (3G) network, a fourth generation (4G) network, a fifth generation (5G) network, a Long-Term Evolution (LTE), an LTE Advanced Network, a Global System for Mobile Communications (GSM) network, a Universal Mobile Telecommunications System (UMTS) network, and the like. Moreover, the network(s) 112 can include any type of network, such as the Internet, an intranet, a Virtual Private Network (VPN), a Voice over Internet Protocol (VoIP) network, a wireless network (e.g., Bluetooth), a cellular network, a satellite network, combinations thereof, etc. The network(s) 112 can include communications network components such as, but not limited to gateways routers, servers, and registrars, which enable communication across the network(s) 112. In one implementation, the communications network components include multiple ingress/egress routers, which may have one or more ports, in communication with the network(s) 112.

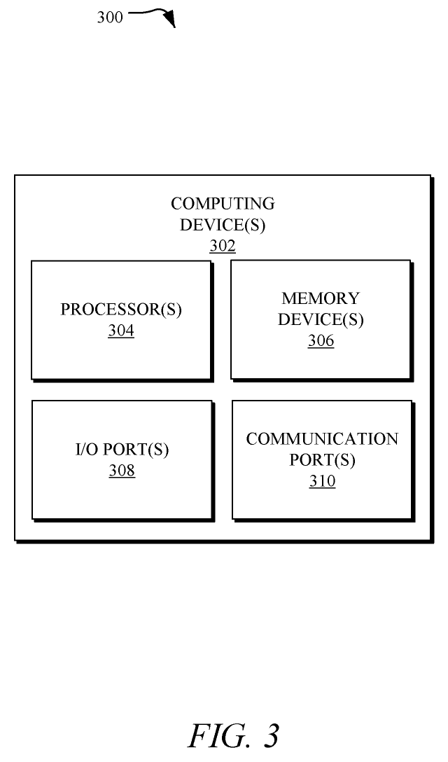

Turning to FIG. 3, a system 300 to process communication data can include one or more computing devices 302 for performing the techniques discussed herein. In one implementation, the one or more computing devices 302 include the computing device 104 and/or one or more servers of the processing system 102 to generate and execute the water production estimation system 114, the pressure estimation system 116, the well plan optimization system 120, output data generation system 122, etc. as a software application and/or a module or algorithmic component of software.

In some instances, the computing device 302 can include a computer, a personal computer, a desktop computer, a laptop computer, a terminal, a workstation, a server device, a cellular or mobile phone, a mobile device, a smart mobile device a tablet, a wearable device (e.g., a smart watch, smart glasses, a smart epidermal device, etc.) a multimedia console, a television, an Internet-of-Things (IoT) device, a smart home device, a medical device, a virtual reality (VR) or augmented reality (AR) device, a vehicle (e.g., a smart bicycle, an automobile computer, etc.), and/or the like. The computing device 302 may be integrated with, form a part of, or otherwise be associated with the systems 100–300. It will be appreciated that specific implementations of these devices may be of differing possible specific computing architectures not all of which are specifically discussed herein but will be understood by those of ordinary skill in the art.

The computing device 302 may be a computing system capable of executing a computer program product to execute a computer process. Data and program files may be input to the computing device 302, which reads the files and executes the programs therein. Some of the elements of the computing device 302 include one or more processors 304, one or more memory devices 306, and/or one or more ports, such as input/output (IO) port(s) 308 and communication port(s) 310. Additionally, other elements that will be recognized by those skilled in the art may be included in the computing device 302 but are not explicitly depicted in FIG. 3 or discussed further herein. Various elements of the computing device 302 may communicate with one another by way of the communication port(s) 310 and/or one or more communication buses, point-to-point communication paths, or other communication means.

The processor 304 may include, for example, a central processing unit (CPU), a microprocessor, a microcontroller, a digital signal processor (DSP), and/or one or more internal levels of cache. There may be one or more processors 304, such that the processor 304 comprises a single central-processing unit, or a plurality of processing units capable of executing instructions and performing operations in parallel with each other, commonly referred to as a parallel processing environment.

The computing device 302 may be a conventional computer, a distributed computer, or any other type of computer, such as one or more external computers made available via a cloud computing architecture. The presently described technology is optionally implemented in software stored on the data storage device(s) such as the memory device(s) 306, and/or communicated via one or more of the I/O port(s) 308 and the communication port(s) 310, thereby transforming the computing device 302 in FIG. 3 to a special purpose machine for implementing the operations described herein. Moreover, the computing device 302, as implemented in the systems 100–300, receives various types of input data (e.g., the sensor data, well data) and transforms the data through various stages of the data flow into new types of data files (e.g., well plan optimization data). Moreover, these new data files are transformed further into output data and sent to the computing device 104 to provide information regarding the data, which enables the computing device 302 to do something it could not do before— using probabilistic water forecasts with pressure prediction simulations to optimize well development plans.

Additionally, the systems and operations disclosed herein represent an improvement to the technical field of prediction modeling. For instance, the processing system 102 can generate well optimization data from vast amounts of data from a plurality of oil and gas production systems without human intervention. Moreover, data can be leveraged provide a highly efficient and effective analysis of a large number or oil and gas production systems. These techniques are rooted in technology and could not have existed prior to the advent of prediction modeling.

The one or more memory device(s) 306 may include any non-volatile data storage device capable of storing data generated or employed within the computing device 302, such as computer executable instructions for performing a computer process, which may include instructions of both application programs and an operating system (OS) that manages the various components of the computing device 302. The memory device(s) 306 may include, without limitation, magnetic disk drives, optical disk drives, solid state drives (SSDs), flash drives, and the like. The memory device(s) 306 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory device(s) 306 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the memory device(s) 306 which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computing device 302 includes one or more ports, such as the I/O port(s) 308 and the communication port(s) 310, for communicating with other computing, network, or vehicle computing devices. It will be appreciated that the I/O port 308 and the communication port 310 may be combined or separate and that more or fewer ports may be included in the computing device 302.

The I/O port 308 may be connected to an I/O device, or other device, by which information is input to or output from the computing device 302. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing device 302 via the I/O port 308. Similarly, the output devices may convert electrical signals received from the computing device 302 via the I/O port 308 into signals that may be sensed as output by a human, such as sound, light, and/or touch. The input device may be an alphanumeric input device, including alphanumeric and other keys for communicating information and/or command selections to the processor 304 via the I/O port 308. The input device may be another type of user input device including, but not limited to direction and selection control devices, such as a mouse, a trackball, cursor direction keys, a joystick, and/or a wheel; one or more sensors, such as a camera, a microphone, a positional sensor, an orientation sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing device 302 via the I/O port 308. For example, an electrical signal generated within the computing device 302 may be converted to another type of signal, and/or vice-versa. In one implementation, the environment transducer devices sense characteristics or aspects of an environment local to or remote from the computing device 302, such as, light, sound, temperature, pressure, magnetic field, electric field, chemical properties, physical movement, orientation, acceleration, gravity, and/or the like.

In one implementation, the communication port 310 is connected to the network(s) 112 so the computing device 302 can receive network data useful in executing the methods and systems set out herein as well as transmitting information and network configuration changes determined thereby. Stated differently, the communication port 310 connects the computing device 302 to one or more communication interface devices configured to transmit and/or receive information between the computing device 302 and other devices by way of one or more wired or wireless communication networks or connections. Examples of such networks or connections include, without limitation, Universal Serial Bus (USB), Ethernet, Wi-Fi, Bluetooth®, Near Field Communication (NFC), and so on. One or more such communication interface devices may be utilized via the communication port 310 to communicate with one or more other machines, either directly over a point-to-point communication path, over a wide area network (WAN) (e.g., the Internet), over a local area network (LAN), over a cellular network (e.g., third generation (3G), fourth generation (4G), Long-Term Evolution (LTE), fifth generation (5G), etc.) or over another communication means. Further, the communication port 310 may communicate with an antenna or other link for electromagnetic signal transmission and/or reception.

In an example, the processing system 102, the water production estimation system 114, the pressure estimation system 116, the well plan optimization system 120, output data generation system 122, etc., and/or other software, modules, services, and operations discussed herein may be embodied by instructions stored on the memory device(s) 306 and executed by the processor 304.

The system set forth in FIG. 3 is but one possible example of a computing device 302 or computer system that may be configured in accordance with aspects of the present disclosure. It will be appreciated that other non-transitory tangible computer-readable storage media storing computer-executable instructions for implementing the presently disclosed technology on a computing system may be utilized. In the present disclosure, the methods disclosed may be implemented as sets of instructions or software readable by the computing device 302.

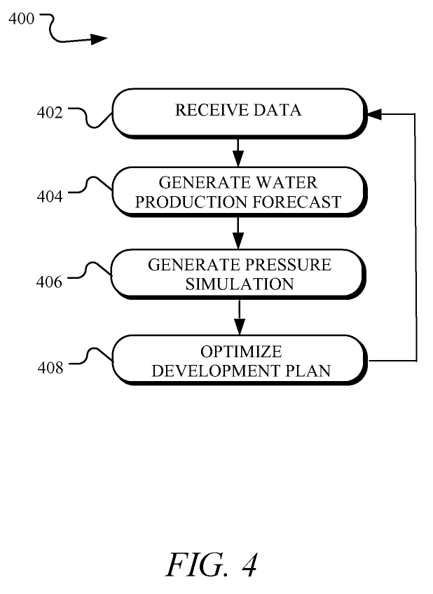

FIG. 4 depicts an example method 400 for optimizing a development plan for a natural resource production system, which can be performed by any of the systems 100–300 discussed herein. The method 400 can, in some instances, occur in real time.

At operation 402, the method 400 can receive data associated with a natural resource production system. In an implementation, the input data is received via the communication interface(s) 118 from at least one of the computing device 104, the one or more sensors 106, or the one or more databases 110.

At operation 404, the method 400 can process the data generate the water production forecast.

At operation 406, the method 400 can generate a pressure simulation using the water production forecast.

At operation 408, the method 400 can optimize the development plan using the water production forecast and/or the pressure simulation. In an implementation, output data controlling the natural resource production system to optimize the system may be generated using method 400. In an implementation, one or more of the graphical representations illustrated in FIGS. 5 and 6 may be generated using method 400. In an implementation, operations 402-408 may repeat using the optimized development plan, thereby continuously optimizing the development plan.

It is to be understood that the specific order or hierarchy of operations in the methods depicted in FIG. 4 and throughout this disclosure are instances of example approaches and can be rearranged while remaining within the disclosed subject matter. For instance, any of the operations depicted in FIG. 4 may be omitted, repeated, performed in parallel, performed in a different order, and/or combined with any other of the operations depicted in FIG. 4 or discussed herein.

The system and methods described herein facilitate decisions to optimize well plans by disentangling the complex interactions of well completions, geology, and well spacing.

Furthermore, any term of degree such as, but not limited to, “substantially,” as used in the description and the appended claims, should be understood to include an exact, or a similar, but not exact configuration. Similarly, the terms “about” or “approximately,” as used in the description and the appended claims, should be understood to include the recited values or a value that is three times greater or one third of the recited values. For example, about 3 mm includes all values from 1 mm to 9 mm, and approximately 50 degrees includes all values from 16.6 degrees to 150 degrees.

Lastly, the terms “or” and “and/or,” as used herein, are to be interpreted as inclusive or meaning any one or any combination. Therefore, “A, B, or C” or “A, B, and/or C” mean any of the following: “A,” “B,” or “C”; “A and B”; “A and C”; “B and C”; “A, B and C.” An exception to this definition will occur only when a combination of elements, functions, steps or acts are in some way inherently mutually exclusive.

While the present disclosure has been described with reference to various implementations, it will be understood that these implementations are illustrative and that the scope of the present disclosure is not limited to them. Many variations, modifications, additions, and improvements are possible. More generally, implementations in accordance with the present disclosure have been described in the context of particular implementations. Functionality may be separated or combined differently in various implementations of the disclosure or described with different terminology. These and other variations, modifications, additions, and improvements may fall within the scope of the disclosure as defined in the claims that follow.

What is claimed is:

1. A system for optimizing a development plan for a natural resource production system, the system comprising:a processing system in communication with a computing device, one or more sensors and one or more databases over a network, the processing system obtaining data associated with the natural resource production system from at least one of the computing device, the one or more sensors or the one or more databases;a water production estimation system generating water production forecast data using the data, the water production forecast data used by a pressure estimation system to generate pressure simulation data; anda well plan optimization system using the pressure simulation data and the water production forecast data to generate an optimized development plan.

2. The system of claim 1 further comprising:an output data generation system generating a notification associated with the optimized development plan, the processing system configured to transmit the notification to the computing device to cause the notification to be presented using one or more output systems of the computing device.

3. The system of claim 2, wherein the notification includes a plot of at least one of the water production forecast data or the pressure simulation data.

4. The system of claim 1, wherein the well plan optimization system is configured to generate at least one of one or more pressure maps or water forecasts by area.

5. The system of claim 4, wherein the one or more pressure maps are linked to an associated well permit.

6. The system of claim 4, wherein the one or more pressure maps indicate if a planned well needs additional structure.

7. The system of claim 1, wherein the well plan optimization system is configured to adjust at least one of a drilling operation or a well operation using the optimized development plan.

8. A method for optimizing a development plan for a natural resource production system, the method comprising:receiving data associated with the natural resource production system from at least one of a computing device, one or more sensors or one or more databases;generating water production forecast data using the data;generating pressure simulation data using the water production forecast data; andgenerating an optimized development plan using the pressure simulation data and the water production forecast data.

9. The method of claim 8, further comprising:generating a notification associated with the optimized development plan; andtransmitting the notification to the computing device to cause the notification to be presented using one or more output systems of the computing device.

10. The method of claim 9, wherein the notification includes a plot of at least one of the water production forecast data or the pressure simulation data.

11. The method of claim 8, further comprising:generating at least one of one or more pressure maps or water forecasts by area.

12. The method of claim 11, further comprising:linking the one or more pressure maps to an associated well permit.

13. The method of claim 11, wherein the one or more pressure maps indicate if a planned well needs additional structure.

14. The method of claim 8, further comprising:adjusting at least one of a drilling operation or a well operation using the optimized development plan.

15. One or more tangible non-transitory computer-readable storage media storing computer- executable instructions for performing a computer process on a computing system, the computer process comprising:receive data associated with a natural resource production system;generate water production forecast data using the data;generate pressure simulation data using the water production forecast data; andgenerate an optimized development plan using the pressure simulation data and the water production forecast data.

16. The one or more tangible non-transitory computer-readable storage media storing computer-executable instructions for performing the computer process on the computing system of claim 15, the computer process further comprising:generate a notification associated with the optimized development plan; andtransmit the notification to a computing device to cause the notification to be presented using one or more output systems of the computing device.

17. The one or more tangible non-transitory computer-readable storage media storing computer-executable instructions for performing the computer process on the computing system of claim 16, wherein the notification includes a plot of at least one of the water production forecast data or the pressure simulation data.

18. The one or more tangible non-transitory computer-readable storage media storing computer-executable instructions for performing the computer process on the computing system of claim 15, the computer process further comprising:
generate at least one of one or more pressure maps or water forecasts by area.

19. The one or more tangible non-transitory computer-readable storage media storing computer-executable instructions for performing the computer process on the computing system of claim 18, the computer process further comprising:link the one or more pressure maps to an associated well permit.

20. The one or more tangible non-transitory computer-readable storage media storing computer-executable instructions for performing the computer process on the computing system of claim 15, the computer process further comprising:adjust at least one of a drilling operation or a well operation using the optimized development plan.
